(19) United States
(12) Patent Application Publication
(10) Pub. No.: US 2023/0422397 A1
(43) Pub. Date: Dec. 28, 2023

(54) WIRING CIRCUIT BOARD

(71) Applicant: NITTO DENKO CORPORATION, Osaka (JP)

(72) Inventors: Takahiro IKEDA, Osaka (JP); Taketo ISHIKAWA, Osaka (JP); Yuki TAKEDA, Osaka (JP); Hironori KUWAYAMA, Osaka (JP); Kyotaro YAMADA, Osaka (JP)

(73) Assignee: NITTO DENKO CORPORATION, Osaka (JP)

(21) Appl. No.: 18/339,005

(22) Filed: Jun. 21, 2023

(30) Foreign Application Priority Data
Jun. 23, 2022 (JP) 2022-101183

(51) Int. Cl. H05K 1/03; H05K 3/46

(52) U.S. Cl. CPC H05K 1/036; H05K 3/467; H05K 2203/0315

(57) ABSTRACT

A wiring circuit board includes a metal supporting board, first and second metal thin films, an insulating layer, and a conductive layer, where the resistance between the conductive layer and metal supporting board are lowered. The first metal thin film is disposed on one surface of the metal supporting board in the thickness direction, with the insulating layer having a through hole. The second metal thin film is disposed on one surface of the insulating layer in the thickness direction with the conductive layer disposed thereon. In the through hole, the first and second metal thin films, whose surfaces contact, are disposed between the metal supporting board and the conductive layer, and the other surface of the first metal thin film is in contact with the one surface of the metal supporting board. The other surface of the second metal thin film is in contact with the conductive layer.

### CROSS-REFERENCE TO RELATED APPLICATION

The present application claims priority from Japanese Patent Application No. 2022-101183 filed on Jun. 23, 2022, the content of which is hereby incorporated by reference into this application.

### TECHNICAL FIELD

The present invention relates to a wiring circuit board.

### BACKGROUND ART

There has been a known wiring circuit board including a metal supporting board, a first metal thin film, an insulating layer, a second metal thin film, and a ground layer (for example, see Patent document 1 below).

In the wiring circuit board described in Patent Document 1, the first metal thin film is disposed on an upper surface of the metal supporting board. The insulating layer is disposed on an upper surface of the first metal thin film. The first metal thin film and the insulating layer commonly have an opening portion penetrating them in the thickness direction. The opening portion of the first metal thin film is formed by removing the first metal thin film that is uncovered at the opening portion of the insulating layer.

The second metal thin film and the ground layer are disposed in the above-described opening portion, and electrically connected to the metal supporting board through the second metal thin film in the opening portion.

### CITATION LIST

### Patent Document

Patent Document 1: Japanese Unexamined Patent Publication No. 2022-30666

### SUMMARY OF THE INVENTION

### Problem to be Solved by the Invention

In the formation of the first metal thin film of the wiring circuit board described in Patent Document 1, the part that is uncovered at the opening portion of the insulating layer needs being removed. Thus, the formation of the first metal thin film requires time and effort.

Thus, to simply form the first metal thin film, an attempt is made to leave the above-described part in the opening portion without removing it.

In the attempt, when the insulating layer is formed by photolithography after the formation of the first metal thin film, the first metal thin film is heated together with the insulating layer that was exposed to light. Then, the first metal thin film that is uncovered at the opening portion of the insulating layer is exposed to the air and oxidized. When the first metal thin film consists of chromium alone, the above-described oxidation notably increases the resistance of the first metal thin film. This causes a disadvantage that the resistance between the ground layer and the metal supporting board cannot be lowered.

The present invention provides a wiring circuit board in which the first metal thin film can simply be formed and in which, even when the first metal thin film and the second metal thin film intervene between the conductive layer and the metal supporting board, the resistance between the conductive layer and the metal supporting board can be lowered.

### Means for Solving the Problem

The present invention [1] includes a wiring circuit board comprising: a metal supporting board; a first metal thin film disposed on one surface of the metal supporting board in a thickness direction; an insulating layer disposed on one surface of the first metal thin film in the thickness direction and having a through hole penetrating in the thickness direction; a second metal thin film disposed on one surface of the insulating layer; and a conductive layer disposed on one surface of the second metal thin film, wherein, in the through hole, the first metal thin film and the second metal thin film are disposed between the metal supporting board and the conductive layer, the other surface of the first metal thin film is in contact with the one surface of the metal supporting board, the other surface of the second metal thin film is in contact with the one surface of the first metal thin film, and the other surface of the conductive layer is in contact with the one surface of the second metal thin film, and wherein, at least, a material of the first metal thin film is an alloy containing chromium.

In this wiring circuit board, the first metal thin film and the second metal thin film are disposed between the metal supporting board and the conductive layer in the through hole. Thus, the removal of the first metal thin film is not required, and the first metal thin film can simply be formed.

Furthermore, in this wiring circuit board, the material of the first metal thin film is an alloy containing chromium. Thus, even when the first metal thin film and the second metal thin film intervene between the conductive layer and the metal supporting board, the resistance between the conductive layer and the metal supporting board can be lowered.

The present invention [2] includes the wiring circuit board described in the above-described [1], wherein the content ratio of the chromium in the alloy is 50% by mass or less.

The present invention [3] includes the wiring circuit board described in the above-described [1] or [2], wherein the alloy further contains at least one metal selected from the group consisting of nickel, titanium, tungsten, and molybdenum.

The present invention [4] includes the wiring circuit board described in the above-described [1] or [2], wherein a material of the second metal thin film is a second alloy containing chromium.

In this wiring circuit board, the material of the second metal thin film is the second alloy containing chromium, and thus the resistance between the conductive layer and the metal supporting board can even more be lowered.

The present invention [5] includes the wiring circuit board described in the above-described [4], wherein the content ratio of the chromium in the second alloy is 50% by mass or less.

The present invention [6] includes the wiring circuit board described in the above-described [4], wherein the alloy further contains at least one metal selected from the group consisting of nickel, titanium, tungsten, and molybdenum.

The present invention [7] includes the wiring circuit board described in the above-described [4], wherein the alloy and the second alloy are composed of the same composition.

In this wiring circuit board, the alloy of the first metal thin film and the second alloy of the second metal thin film are composed of the same composition, and thus the first metal thin film and the second metal thin film can efficiently be formed using the same device.

Furthermore, by using the same type of etching solution, the first metal thin film and the second metal thin film can efficiently be patterned.

The present invention [8] includes the wiring circuit board described in the above-described [1] or [2], wherein the first metal thin film includes: a first metal layer; and a first oxidized layer disposed on one surface of the first metal layer in the thickness direction.

The first metal thin film includes the first oxidized layer, and thus the resistance of the first metal thin film tends to increase.

However, in this wiring circuit board, the material of the first metal thin film is the alloy containing chromium, and thus the resistance between the conductive layer and the metal supporting board can be lowered.

The present invention [9] includes the wiring circuit board described in the above-described [1] or [2], wherein the metal supporting board includes: a metal supporting layer; and a surface metal layer disposed on one surface of the metal supporting layer in the thickness direction and having higher electrical conductivity than electrical conductivity of the metal supporting layer.

In this wiring circuit board, the metal supporting board includes the surface metal layer having higher electrical conductivity than that of the metal supporting layer, and thus the resistance between the conductive layer and the metal supporting layer can even more be lowered.

### Effects of the Invention

In the wiring circuit board of the present invention, the first metal thin film can simply be formed and, even when the first metal thin film and the second metal thin film intervene between the conductive layer and the metal supporting board, the resistance between the conductive layer and the metal supporting board can be lowered.

### BRIEF DESCRIPTION OF THE DRAWINGS

FIG. 1 is a cross-sectional view of one embodiment of the wiring circuit board of the present invention.

FIGS. 2A to 2E illustrate steps of producing the wiring circuit board illustrated in FIG. 1. FIG. 2A illustrates a step of forming a first metal thin film. FIG. 2B illustrates a step of forming an insulating layer. FIG. 2C illustrates a step of forming a second metal thin film.

FIG. 2D illustrates a step of forming a conductive layer. FIG. 2E illustrates a step of forming an insulating cover layer.

FIG. 3 is a cross-sectional view of the wiring circuit board of a first variation.

### DESCRIPTION OF THE EMBODIMENT

1. One Embodiment of Wiring Circuit Board of Present Invention

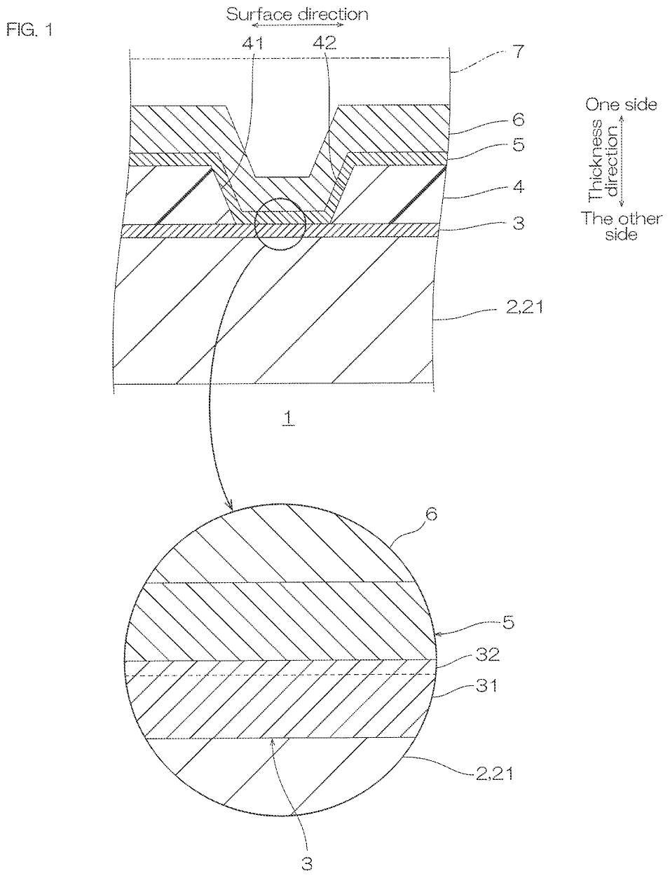

With reference to FIG. 1, one embodiment of the wiring circuit board of the present invention is described.

As illustrated in FIG. 1, a wiring circuit board 1 has a thickness. The wiring circuit board 1 has a sheet shape. The wiring circuit board 1 extends in a surface direction. The surface direction is orthogonal to a thickness direction. The wiring circuit board 1 includes a metal supporting board 2, a first metal thin film 3, an insulating layer 4, a second metal thin film 5, and a conductive layer 6. The wiring circuit board 1 further includes an insulating cover layer 7.

2. Metal Supporting Board 2

The metal supporting board 2 is disposed at the other end portion of the wiring circuit board 1 in the thickness direction. The metal supporting board 2 extends in the surface direction. In the present embodiment, the metal supporting board 2 includes only a metal supporting layer 21. The metal supporting layer 21 forms the other surface of the wiring circuit board 1 in the thickness direction. Examples of the material of the metal supporting layer 21 include iron, stainless-steel, copper, and copper alloy, and preferable examples thereof include stainless-steel and copper alloy. The metal supporting layer 21 has a thickness of, for example, 1 μm or more, preferably 10 μm or more, and, for example, 1000 μm or less, preferably 500 μm or less.

3. First Metal Thin Film 3

The first metal thin film 3 is disposed on one surface of the metal supporting board 2 in the thickness direction. The other surface of the first metal thin film 3 in the thickness direction is in contact with the one surface of the metal supporting board 2 in the thickness direction. Specifically, the other surface of the first metal thin film 3 in the thickness direction is in contact with one surface of the metal supporting layer 21 in the thickness direction. Preferably, the first metal thin film 3 is in contact with the whole of the one surface of the metal supporting layer 21 in the thickness direction. The first metal thin film 3 extends in the surface direction. The material of the first metal thin film 3 is an alloy. The alloy contains chromium. The alloy contains, in addition to chromium, for example, at least one metal selected from the group consisting of nickel, titanium, tungsten, and molybdenum. The alloy containing at least the one metal as described above can suppress the increase in the resistance of the first metal thin film 3 even when the first metal thin film 3 is oxidized. Nnickel and titanium are preferable as the metal. Cr—Ti alloys and Ni—Cr alloys are preferable as the alloy.

The content ratio of chromium in the alloy is, for example, 90% by mass or less, preferably 50% by mass or less, more preferably 30% by mass or less, and, for example, 1% by mass or more, preferably 5% by mass or more, more preferably 10% by mass or more.

When the content ratio of chromium in the alloy is the above-described upper limit or less, the resistance of the first metal thin film 3 can be reduced. More specifically, the increase in the resistance of the first metal thin film 3 caused by the first oxidized layer 32 included in the first metal thin film 3 can be suppressed. Thus, the resistance between the conductive layer 6 and the metal supporting board 2, which is described below, can even more be lowered.

When the content ratio of chromium in the alloy is the above-described lower limit or more, the adhesive properties of the first metal thin film 3 to the insulating layer 4 is secured. The content ratio of chromium in the alloy is obtained by TEM-EDX (energy dispersive X-ray spectroscopy).

The content ratio of the metal other than chromium in the alloy is the remainder of the alloy with respect to the above-described content ratio of chromium. The content ratio of the metal in the alloy can be obtained by TEM-EDX.

3.1 First Metal Layer 31

The first metal thin film 3 includes a first metal layer 31 and a first oxidized layer 32. The first metal layer 31 is disposed at the other end portion of the first metal thin film 3 in the thickness direction. The first metal layer 31 extends in the surface direction. The first metal layer 31 is in contact with the whole of the one surface of the metal supporting board 2 in the thickness direction. Examples of the material of the first metal thin film 3 include the above-described alloys. The first metal layer 31 has a thickness of, for example, 1 nm or more, preferably 10 nm or more, and, for example, 500 nm or less, preferably 250 nm or less.

3.2 First Oxidized Layer 32

The first oxidized layer 32 is disposed at one end portion of the first metal thin film 3 in the thickness direction. The first oxidized layer 32 is disposed on one surface of the first metal layer 31 in the thickness direction. That is to say, the first oxidized layer 32 is in contact with the whole of the one surface of the first metal layer 31 in the thickness direction. The first oxidized layer 32 is formed by the heating of the insulating layer 4 (by heating the insulating layer 4 after exposing the insulating layer 4 to light) in the production of the insulating layer 4 as described below. The material of the first oxidized layer 32 is a composite oxide of the above-described alloy. The first oxidized layer 32 has a thickness of, for example, 0.5 nm or more, preferably 1 nm or more, and, for example, 20 nm or less, preferably 10 nm or less. The ratio of the thickness of the first oxidized layer 32 to the thickness of the first metal layer 31 is, for example, 0.001 or more, preferably 0.002 or more, and, for example, 1 or less, preferably 0.5 or less. The boundary between the first metal layer 31 and the first oxidized layer 32, as illustrated in the enlarged view in FIG. 1, is shown in a broken line, but the boundary is allowed not to be clearly observed. The presence of the first oxidized layer 32 is determined by TEM-EDX.

The first metal thin film 3 has a thickness of, for example, 1 nm or more, preferably 10 nm or more, and, for example, 500 nm or less, preferably 250 nm or less.

4. Insulating Layer 4

The insulating layer 4 is disposed on one surface of the first metal thin film 3 in the thickness direction. The insulating layer 4 is in contact with the one surface of the first metal thin film 3 in the thickness direction. The insulating layer 4 is disposed on one surface of the first oxidized layer 32 in the thickness direction and is in contact with the one surface of the first oxidized layer 32. The insulating layer 4 extends in the surface direction. The insulating layer 4 is an insulating base layer.

The insulating layer 4 includes a through hole 41. The through hole 41 penetrates the insulating layer 4 in the thickness direction. In the present embodiment, the through hole 41 has an approximately tapered shape in the cross section while the cross-sectional area of the opening of the through hole 41 gradually increases toward one side in the thickness direction. The through hole 41 is defined by an inner peripheral surface 42 of the insulating layer 4. Examples of the material of the insulating layer 4 include insulating resin. Examples of the insulating resin include polyimide. The insulating layer 4 has a thickness of, for example, 1 μm or more, preferably 5 μm or more, and, for example, 100 μm or less, preferably 50 μm or less.

5. Second Metal Thin Film 5

The second metal thin film 5 is disposed on one surface of the insulating layer 4. Specifically, the second metal thin film 5 is in contact with the one surface of the insulating layer 4 in the thickness direction and the inner peripheral surface 42 of the insulating layer 4. Furthermore, in the through hole 41, the second metal thin film 5 is disposed on the one surface of the first metal thin film 3 in the thickness direction. Specifically, in the through hole 41, the other surface of the second metal thin film 5 in the thickness direction is in contact with the one surface of the first metal thin film 3 in the thickness direction. The second metal thin film 5 in contact with the insulating layer 4 and the second metal thin film 5 in contact with the first metal thin film 3 are continuous.

Examples of the material of the second metal thin film 5 include a second alloy. The second alloy contains chromium. The second alloy contains, in addition to chromium, for example, at least one metal selected from the group consisting of nickel, titanium, tungsten, and molybdenum. The alloy containing at least the one metal as described above can suppress the increase in the resistance of the second metal thin film 5 even when the second metal thin film 5 is oxidized. Preferable examples of the metal include nickel and titanium. Preferable examples of the second alloy include Cr—Ti alloys and Ni—Cr alloys. Furthermore, preferably, the second alloy of the second metal thin film 5 and the alloy of the first metal thin film 3 are composed of the same composition.

When the second alloy of the second metal thin film 5 and the alloy of the first metal thin film 3 are composed of the same composition, the first metal thin film 3 and the second metal thin film 5 can efficiently be formed with the same device. Furthermore, by using the same type of etching solution, the first metal thin film 3 and the second metal thin film 5 can efficiently be patterned.

The content ratio of chromium in the second alloy is, for example, 90% by mass or less, preferably 50% by mass or less, more preferably 30% by mass or less, and, for example, 1% by mass or more, preferably 5% by mass or more, more preferably 10% by mass or more.

When the content ratio of chromium in the second alloy is the above-described upper limit or less, the resistance of the second metal thin film 5 can be reduced. More specifically, the increase in the resistance of the second metal thin film 5 due to the oxidation of the second metal thin film 5 can be suppressed. Thus, the resistance between the conductive layer 6 and the metal supporting board 2, which is described below, can even more be lowered.

When the content ratio of chromium in the second alloy is the above-described lower limit or more, the adhesive properties of the second metal thin film 5 to the insulating layer 4 is secured. The content ratio of chromium in the second alloy is obtained by TEM-EDX.

When the second alloy of the second metal thin film 5 and the alloy of the first metal thin film 3 are composed of the same composition, the content ratio of chromium in the second alloy and the content ratio of chromium in the alloy are the same.

The content ratio of the metal other than chromium in the second alloy is the remainder of the alloy with respect to the above-described content ratio of chromium. The content ratio of the metal in the second alloy can be obtained by TEM-EDX.

The second metal thin film 5 has a thickness of, for example, 1 nm or more, preferably 10 nm or more, and, for example, 500 nm or less, preferably 250 nm or less.

6. Conductive Layer 6

The conductive layer 6 is disposed on one surface of the second metal thin film 5. The other surface of the conductive layer 6 in the thickness direction is in contact with the one surface of the second metal thin film 5 in the thickness direction. In this manner, the first metal thin film 3 and the second metal thin film 5 are disposed between the metal supporting board 2 and the conductive layer 6 so as to be in contact with the metal supporting board 2 and the conductive layer 6, respectively, in the through hole 41. In the present embodiment, the conductive layer 6 is a ground layer. The conductive layer 6 is electrically grounded (earthed) with the metal supporting board 2 through the first metal thin film 3 and the second metal thin film 5 in the through hole 41. Examples of the material of the conductive layer 6 include copper, silver, gold, iron, aluminum, chromium, and alloys thereof. Preferable examples of the material of the conductive layer 6 include copper. The conductive layer 6 has a thickness, for example, 1 μm or more, preferably 3 μm or more, and, for example, 50 μm or less, preferably 30 μm or less.

7. Insulating Cover Layer 7

The insulating cover layer 7 shown in a phantom line is disposed at one end portion of the wiring circuit board 1 in the thickness direction. The insulating cover layer 7 forms the one surface of the wiring circuit board 1 in the thickness direction. Although not illustrated, the insulating cover layer 7 is disposed on the one surface of the insulating layer 4 in the thickness direction. The insulating cover layer 7 covers the conductive layer 6. Examples of the material of the insulating cover layer 7 include insulating resin. Examples of the insulating resin include polyimide. The insulating cover layer 7 has a thickness of, for example, 1 μm or more, and, for example, 100 μm or less.

8. Method of Producing Wiring Circuit Board 1

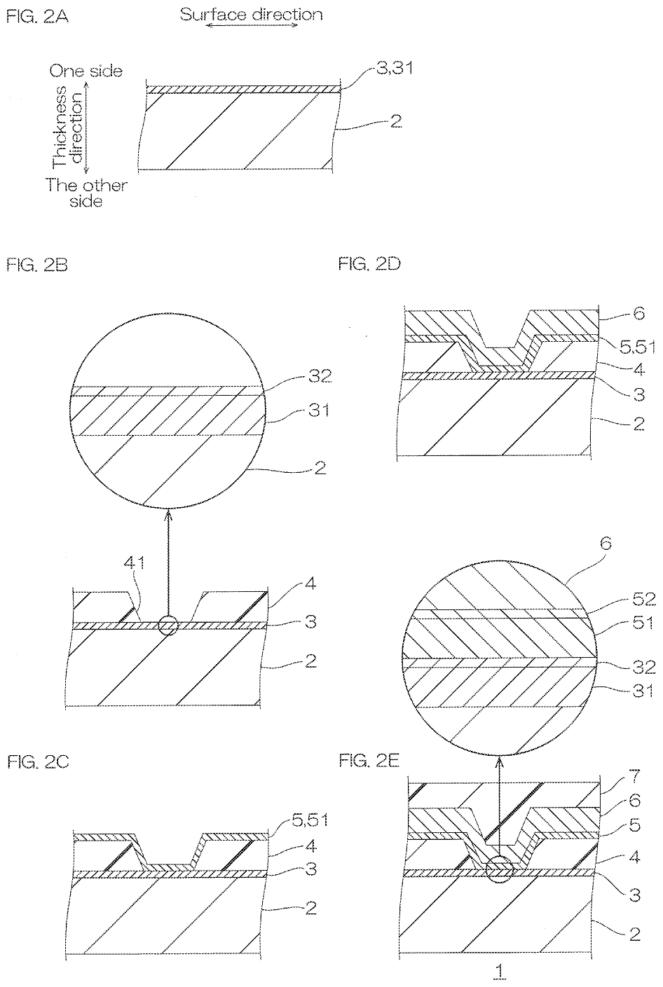

With reference to FIGS. 2A to 2E, a method of producing the wiring circuit board 1 is described.

As illustrated in FIG. 2A, first, the first metal thin film 3 is disposed on the one surface of the metal supporting board 2 in the thickness direction. For example, by thin film formation process, preferably by dry process, more preferably by sputtering, the first metal thin film 3 is formed on the one surface of the metal supporting board 2. In sputtering, a target made of the above-described alloy is used, or each of chromium and a metal other than chromium (such as Ti when the alloy is a Cr—Ti alloy, or Ni when the alloy is a Ni—Cr alloy) is used as the target. In this step, the first metal thin film 3 is yet to include the first oxidized layer 32 (see FIG. 2B), and includes only the first metal layer 31.

As illustrated in FIG. 2B, next, the insulating layer 4 is disposed on the one surface of the first metal thin film 3 in the thickness direction. For example, a varnish containing photosensitive insulating resin is applied on the whole of the one surface of the first metal thin film 3. Thereafter, by photolithography, the insulating layer 4 having the through hole 41 is formed. When the insulating layer 4 is formed by photolithography, the exposed insulating layer 4 is heated (the insulating layer 4 is heated after being exposed to light). Under an air atmosphere, for example, the insulating layer 4 is heated to 100° C. or more, preferably 150° C. or more, and, for example, 500° C. or less. By the above-described heating, the first oxidized layer 32 is formed on the one surface of the first metal layer 31.

As illustrated in FIG. 2C, next, the second metal thin film 5 is disposed on the one surface of the insulating layer 4 in the thickness direction, an inner peripheral surface of the insulating layer 4, and the one surface of the first metal thin film 3 in the through hole 41. For example, thin film formation process, preferably dry process, more preferably sputtering is carried out to form the second metal thin film 5 on the one surface of the insulating layer 4 and the one surface of the first metal thin film 3 in the through hole 41. In sputtering, a target made of the above-described second alloy is used, or each of chromium and a metal other than chromium (such as Ti when the second alloy is a Cr—Ti alloy, or Ni when the second alloy is a Ni—Cr alloy) is used as the target. In this step, the surface of the second metal thin film 5 is not oxidized.

As illustrated in FIG. 2D, next, the conductive layer 6 is disposed on the one surface of the second metal thin film 5 in the thickness direction. For example, conductive pattern formation process, preferably wet process, more preferably plating, even more preferably electrolytic plating is carried out to form the conductive layer 6 on the one surface of the second metal thin film 5 in the thickness direction. In electrolytic plating, for example, electric current is passed from the metal supporting board 2 through the first metal thin film 3 to the second metal thin film 5.

As illustrated in FIG. 2E, after that, the insulating cover layer 7 is disposed on the one surface of the insulating layer 4 so that the insulating cover layer 7 covers the conductive layer 6. For example, a varnish containing photosensitive insulating resin is applied on the whole of the one surface of each of the insulating layer 4 and the conductive layer 6. Thereafter, the insulating cover layer 7 is formed by photolithography. When the insulating cover layer 7 is formed by photolithography, the exposed insulating cover layer 7 is heated (the insulating cover layer 7 is heated after being exposed to light). Under an air atmosphere, the insulating cover layer 7 is heated to, for example, 100° C. or more, preferably 150° C. or more, and, for example, 500° C. or less.

In this manner, the wiring circuit board 1 is produced.

9. Operations and Effects of One Embodiment

This wiring circuit board 1 includes the first metal thin film 3 which is in contact with the metal supporting board 2 in the through hole 41, and thus does not require the removal of the first metal thin film 3 as described in Patent Document 1 and allows for simply formation of the first metal thin film 3.

Further, the wiring circuit board 1 includes the first metal thin film 3 composed of a material that is an alloy containing chromium, and thus the resistance between the conductive layer 6 and the metal supporting board 2 can be lowered even when the first metal thin film 3 and the second metal thin film 5 intervene between the conductive layer 6 and the metal supporting board 2.

On the other hand, the first metal thin film 3 includes the first oxidized layer 32, and thus the resistance of the first metal thin film 3 tends to increase.

However, the wiring circuit board 1 includes the first metal thin film 3 composed of a material that is an alloy containing chromium, and thus the resistance between the conductive layer 6 and the metal supporting board 2 can be lowered.

When the second alloy of the second metal thin film 5 and the alloy of the first metal thin film 3 are composed of the same composition, the first metal thin film 3 and the second metal thin film 5 can simply be formed with the same device. Furthermore, by using the same type of etching solution, the first metal thin film 3 and the second metal thin film 5 can efficiently be patterned.

10. Variation

In each of the following variations, the same members and steps as in the above-described one embodiment are given the same reference numerals, and the detailed descriptions thereof are omitted. Further, unless specified otherwise, the variations can have the same operations and effects as one embodiment does. Furthermore, one embodiment and each variation can appropriately be combined.

10.1 First Variation

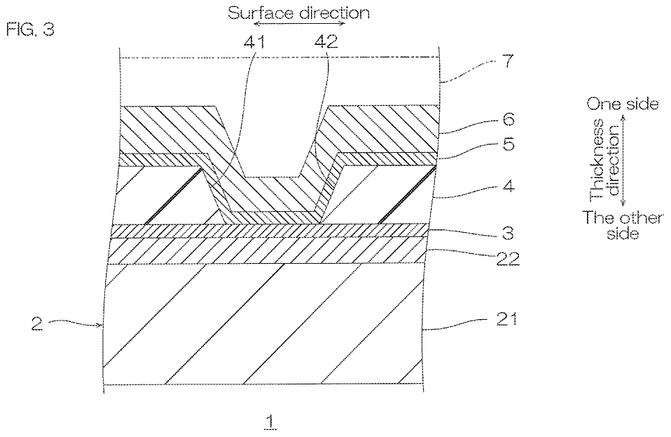

As illustrated in FIG. 3, in the first variation, the metal supporting board 2 includes the metal supporting layer 21 and a surface metal layer 22.

The metal supporting layer 21 has a thickness of, for example, 1 μm or more, preferably 10 μm or more, and, for example, 1000 μm or less, preferably 500 μm or less.

The surface metal layer 22 is disposed at one end portion of the metal supporting board 2 in the thickness direction. The surface metal layer 22 is disposed on one surface of the metal supporting layer 21 in the thickness direction. The surface metal layer 22 is in contact with the one surface of the metal supporting layer 21 in the thickness direction. The surface metal layer 22 is further in contact with the other surface of the first metal thin film 3 (the first metal layer 31) in the thickness direction.

The surface metal layer 22 has higher electrical conductivity than that of the metal supporting layer 21. Examples of the material of the surface metal layer 22 include copper, silver, and gold. These materials may be used singly or in combination. As the material of the surface metal layer 22, copper is preferably used.

The surface metal layer 22 has a thickness of, for example, 0.5 μm or more, preferably 3 μm or more, and, for example, 10 μm or less.

The wiring circuit board 1 of the first variation includes the metal supporting board 2 that includes the surface metal layer 22 having higher electrical conductivity than that of the metal supporting layer 21, and thus the resistance between the conductive layer 6 and the metal supporting layer 21 can even more be lowered.

10.2 Second Variation

Although not illustrated, in the second variation, the material of the second metal thin film 5 is not the second alloy containing chromium, and examples of the material in the second variation include chromium, nickel, titanium, tungsten, and molybdenum. Specifically, examples of the material of the second metal thin film 5 include chromium alone, nickel alone, titanium alone, tungsten alone, and molybdenum alone. The material of the second metal thin film 5 may be an alloy containing at least two metals selected from the group consisting of nickel, titanium, tungsten, and molybdenum.

10.3 Third Variation

Although not illustrated, the second metal thin film 5 may include a second metal layer and a second oxidized layer disposed on one surface of the second metal layer in the thickness direction.

### EXAMPLES

Hereinafter, with reference to Test Examples as Examples, the present invention is more specifically described. The present invention is not limited to Test Examples in any manner. The specific numeral values used in the description below, such as mixing ratios (contents), physical property values, and parameters can be replaced with the corresponding mixing ratios (contents), physical property values, parameters in the above-described “DESCRIPTION OF EMBODIMENTS”, including the upper limit values (numeral values defined with “or less”, and “less than”) or the lower limit values (numeral values defined with “or more”, and “more than”).

### Test Example 1

[Production of First Test Circuit Board Including First Metal Thin Film 3 that is not Oxidation-Treated and DCR Measurement Thereof]

On one surface of a glass plate in the thickness direction, a metal supporting board 2 consisting of copper, a first metal thin film 3 consisting of a Cr—Ti alloy composed of the composition shown in Table 1, and a conductive layer 6 consisting of copper were formed in this order. In this manner, a first test circuit board was produced. The first metal thin film 3 of the first test circuit board was not oxidation-treated (as described below) yet. That is to say, the first metal thin film 3 did not include a first oxidized layer 32 yet but included only a first metal layer 31.

Thereafter, the direct current resistance (DCR) between the metal supporting board 2 and the conductive layer 6 was measured with a digital multimeter.

[Production of Second Test Circuit Board Including Oxidation-Treated First Metal Thin Film 3]

On one surface of a glass plate in the thickness direction, a metal supporting board 2 consisting of copper and a first metal thin film 3 consisting of a Cr—Ti alloy composed of the composition shown in Table 1 were formed in this order. Thereafter, one surface of the first metal thin film 3 was oxidized. In this manner, a first oxidized layer 32 was provided to the first metal thin film 3. In the oxidation, the one surface of the first metal thin film 3 was exposed to oxygen plasma.

Thereafter, a conductive layer 6 consisting of copper was formed on one surface of the first metal thin film 3.

In this manner, a second test circuit board was produced.

Thereafter, the direct current resistance (DCR) between the metal supporting board 2 and the conductive layer 6 was measured with a digital multimeter.

Then, the DCR of the first test circuit board was subtracted from the DCR of the second test circuit board to obtain the difference in DCR. The difference in DCR was shown in Table 1.

### Test Examples 2 to 5

In the same manner as Test Example 1, the first and second test circuit boards were produced, and the differences in DCR were obtained. However, the composition of the first metal thin film 3 was changed in accordance with Table 1. The differences in DCR are shown in Table 1.

### Comparative Test Example 1 (First Metal Thin Film 3 Consisting of Cr Alone)

In the same manner as Test Example 1, the first and second test circuit boards were produced, and the difference in DCR was obtained. However, the material of the first metal thin film 3 was changed to Cr alone. The difference in DCR is shown in Table 1.

### Comparative Test Example 2 (First Metal Thin Film 3 Consisting of Ti Alone)

In the same manner as Test Example 1, the first and second test circuit boards were produced, and the difference in DCR was obtained. However, the material of the first metal thin film 3 was changed to Ti alone in accordance with Table 1. The difference in DCR is shown in Table 1.

### Comparative Test Example 3 (First Metal Thin Film 3 Consisting of Ni Alone)

In the same manner as Test Example 1, the first and second test circuit boards were produced, and the difference in DCR was obtained. However, the material of the first metal thin film 3 was changed to Ni alone in accordance with Table 1. The difference in DCR is shown in Table 1.

### [Consideration]

As shown in Table 1, each of Test Examples 1 and 2 where the material of the first metal thin film 3 is a Cr—Ti alloy demonstrates a small difference in DCR as compared to Comparative Test Example 1 where the material of the first metal thin film 3 is Cr alone. In other words, even when the first metal thin film 3 includes the first oxidized layer 32, the increase in the resistance of the first metal thin film 3 can be suppressed.

In Comparative Test Example 2, the material of the first metal thin film 3 is Ti alone (the content ratio of Cr is 0% by mass), and the content ratio of Ti is 100% by mass, and thus the adhesive properties of the insulating layer 4 to the first metal thin film 3 is evaluated as low.

As shown in Table 1, each of Test Examples 3 to 5 where the material of the first metal thin film 3 is a Ni—Cr alloy demonstrates a small difference in DCR as compared to Comparative Test Example 1 where the material of the first metal thin film 3 is Cr alone. In other words, even when the first metal thin film 3 includes the first oxidized layer 32, the increase in the resistance of the first metal thin film 3 can be suppressed.

In Comparative Test Example 3, the material of the first metal thin film 3 is Ni alone (the content ratio of Cr is 0% by mass), and Ni has magnetic properties, and transmission loss increases at high frequencies. Accordingly, Comparative Test Example 3 is evaluated as inappropriate.

TABLE 1

| | | Value Obtained by Subtracting DCR of | |
|---|---|---|---|
| | | 1st Test Circuit Board from DCR of | |
| | | 2nd Test Circuit Board (mΩ) | |
| | | Cr—Ti Alloy | Ni—Cr Alloy |
| Content Ratio | 100 | 380 | 380 |
| of Cr | | [Comparative Test | [Comparative Test |
| (% by mass) | | Ex. 1*¹] | Ex. 1*¹] |
| | 75 | — | 205 |
| | | | [Test Ex. 3] |
| | 45 | 348 | 46 |
| | | [Test Ex. 1] | [Test Ex. 4] |
| | 20 | 18 | — |
| | | [Test Example2] | |
| | 15 | — | 5.3 |
| | | | [Test Ex. 5] |
| | 0 | 0.9 | 0.5 |
| | | [Comparative Test | [Comparative Test |
| | | Ex. 2*²] | Ex. 3*³] |

*¹Cr alone
*²Ti alone
*³Ni alone

While the illustrative embodiments of the present invention are provided in the above description, such is for illustrative purpose only and it is not to be construed as limiting in any manner. Modification and variation of the present invention that will be obvious to those skilled in the art is to be covered by the following claims.

### DESCRIPTION OF REFERENCE NUMERALS

1 wiring circuit board
2 metal supporting board
3 first metal thin film
4 insulating layer
5 second metal thin film
6 conductive layer
21 metal supporting layer
22 surface metal layer
31 first metal layer
32 first oxidized layer
41 through hole

1. A wiring circuit board comprising:
a metal supporting board;
a first metal thin film disposed on one surface of the metal supporting board in a thickness direction;
an insulating layer disposed on one surface of the first metal thin film in the thickness direction and having a through hole penetrating in the thickness direction;
a second metal thin film disposed on one surface of the insulating layer; and
a conductive layer disposed on one surface of the second metal thin film,
wherein, in the through hole, the first metal thin film and the second metal thin film are disposed between the metal supporting board and the conductive layer, the other surface of the first metal thin film is in contact with the one surface of the metal supporting board, the other surface of the second metal thin film is in contact with the one surface of the first metal thin film, and the other surface of the conductive layer is in contact with the one surface of the second metal thin film, and
wherein, at least, a material of the first metal thin film is an alloy containing chromium.

2. The wiring circuit board according to claim 1, wherein the content ratio of the chromium in the alloy is 50% by mass or less.

3. The wiring circuit board according to claim 1, wherein the alloy further contains at least one metal selected from the group consisting of nickel, titanium, tungsten, and molybdenum.

4. The wiring circuit board according to claim 1, wherein a material of the second metal thin film is a second alloy containing chromium.

5. The wiring circuit board according to claim 4, wherein the content ratio of the chromium in the second alloy is 50% by mass or less.

6. The wiring circuit board according to claim 4, wherein the second alloy further contains at least one metal selected from the group consisting of nickel, titanium, tungsten, and molybdenum.

7. The wiring circuit board according to claim 4, wherein the alloy and the second alloy are composed of the same composition.

8. The wiring circuit board according to claim 1, wherein the first metal thin film includes:
a first metal layer; and
a first oxidized layer disposed on one surface of the first metal layer in the thickness direction.

9. The wiring circuit board according to claim 1, wherein the metal supporting board includes:
a metal supporting layer; and
a surface metal layer disposed on one surface of the metal supporting layer in the thickness direction and having higher electrical conductivity than electrical conductivity of the metal supporting layer.
